(19) United States
(12) Patent Application Publication
(10) Pub. No.: US 2014/0320836 A1
(43) Pub. Date: Oct. 30, 2014

(54) LITHOGRAPHY APPARATUS, LITHOGRAPHY METHOD, AND METHOD FOR MANUFACTURING DEVICE

(71) Applicant: CANON KABUSHIKI KAISHA, Tokyo (JP)

(72) Inventors: Wataru Yamaguchi, Utsunomiya-shi (JP); Koichi Sentoku, Kawachi-gun (JP); Satoru Oishi, Utsunomiya-shi (JP); Toshihiko Nishida, Utsunomiya-shi (JP); Go Tsuchiya, Tochigi-shi (JP); Hideki Ina, Tokyo (JP)

(73) Assignee: CANON KABUSHIKI KAISHA, Tokyo (JP)

(21) Appl. No.: 14/263,684

(22) Filed: Apr. 28, 2014

(30) Foreign Application Priority Data
Apr. 30, 2013 (JP) 2013-096008

(51) Int. Cl. G03F 7/20

(52) U.S. Cl. CPC G03F 7/70133
USPC 355/67; 355/77

(57) ABSTRACT

An apparatus includes an optical system configured to irradiate a surface of a substrate with a beam, a control unit configured to control a position of the irradiation of the beam, and a first measurement unit and a second measurement unit each configured to measure a position of a mark formed on the substrate. The second measurement unit is placed at a position closer to an optical axis of the optical system than the first measurement unit is. Based on a position measurement value measured by the first measurement unit and position measurement values measured at different timings by the second measurement unit, the control unit controls the position of the beam irradiated to the substrate. The position measurement values measured at the different timings are values obtained from the same mark or values obtained from two marks adjacent to a common shot area.

### BACKGROUND OF THE INVENTION

1. Field of the Invention

The present invention relates to a lithography apparatus for irradiating a substrate with a beam, a lithography method using the lithography apparatus, and a method for manufacturing devices.

2. Description of the Related Art

In recent years, the line width of a pattern to be formed on a substrate has become very narrow due to the high integration and the miniaturization of semiconductor integrated circuits. Accordingly, there is demand for further miniaturization of a pattern to be formed by a lithography process.

A lithography apparatus using a beam (including a light beam such as a krypton fluoride (KrF) beam and an extreme ultraviolet (EUV) beam, and a charged particle beam such as an electron beam and an ion beam, for example) focuses the beam on a substrate and controls the position of the irradiation of the beam, thereby transferring a desired pattern to the substrate. Thus, to meet the demand for the miniaturization of a pattern, it is important to adjust the relative position between the substrate and the beam with high accuracy.

If, however, strain or deformation has occurred in the substrate due to the influence of the heat involved in the lithography process, a shift occurs in the relative position between the substrate and the beam. This reduces the accuracy of position adjustments. Further, the reduction in the accuracy of position adjustments reduces the accuracy of overlaying patterns on respective layers.

Conventionally, the position adjustment is made by a global alignment method. The global alignment method is a method of detecting the positions of alignment marks formed near shot areas on a substrate before the formation of a pattern as a new layer, and obtaining the arrangement of the shot areas (hereinafter referred to as a “lattice arrangement”), thereby making position adjustments.

Thermal deformation of the substrate, however, gradually progresses even in the course of the formation of the pattern. Thus, in view of an increasing demand for the size of a pattern in recent years, a technique for making position adjustments as needed even during the formation of a pattern on one layer is required.

The Japanese Patent Application Laid-Open No. 2000-228351 discusses a technique for detecting marks located at two positions considerably distant from each other before and after the irradiation of a beam by using an electron beam, thereby measuring the rotation or the change in the magnification of a pattern image caused by the thermal expansion of a substrate.

The technique discussed in Japanese Patent Application Laid-Open No. 2000-228351, however, does not take into account the shifts in the position of one of the marks located at two positions considerably distant from each other during the irradiation of the beam for a certain time period. Thus, even if position adjustment is made based on the positions of two different marks considerably distant from each other and measured before and after the irradiation of the beam, the accuracy of position adjustment may be insufficient.

### SUMMARY OF THE INVENTION

According to an aspect of the present invention, an apparatus includes an optical system configured to irradiate a surface of a substrate with a beam, a first measurement unit and a second measurement unit each configured to measure a position of a mark formed on the substrate, the second measurement unit being placed at a position closer to an optical axis of the optical system than the first measurement unit, and a control unit configured to control a position of the beam irradiated to the surface of the substrate based on a position measurement value measured by the first measurement unit and position measurement values measured at different timings by the second measurement unit, wherein the position measurement values measured at the different timings are values obtained from the same mark or values obtained from two marks adjacent to a common shot area.

Further features of the present invention will become apparent from the following description of exemplary embodiments with reference to the attached drawings.

### BRIEF DESCRIPTION OF THE DRAWINGS

FIGS. 1A, 1B, 1C, 1D, and 1E are diagrams illustrating reduction in overlay accuracy resulting from heat.

FIG. 2 is a diagram illustrating a configuration of a drawing apparatus according to a first exemplary embodiment.

FIGS. 3A and 3B are diagrams illustrating alignment marks and position correction marks.

FIGS. 4A and 4B are diagrams illustrating the alignment marks and the position correction marks that are inclined by a degrees.

FIG. 5 is a flow chart illustrating processing for correcting a relative position between an electron beam and a substrate, according to the first exemplary embodiment.

FIG. 6 is a diagram illustrating a relationship between irradiation energy of the electron beam and an amount of deformation of the substrate.

FIG. 7 is a diagram illustrating a configuration of a drawing apparatus including a plurality of position correction sensors for a single column, according to a second exemplary embodiment.

FIG. 8 is a diagram illustrating a step-and-scan operation according to a third exemplary embodiment.

FIG. 9 is a flow chart illustrating processing for correcting a relative position between an electron beam and a substrate, according to the third exemplary embodiment.

FIG. 10 is a diagram illustrating a configuration of a drawing apparatus including a plurality of columns, according to a fourth exemplary embodiment.

### DESCRIPTION OF THE EMBODIMENTS

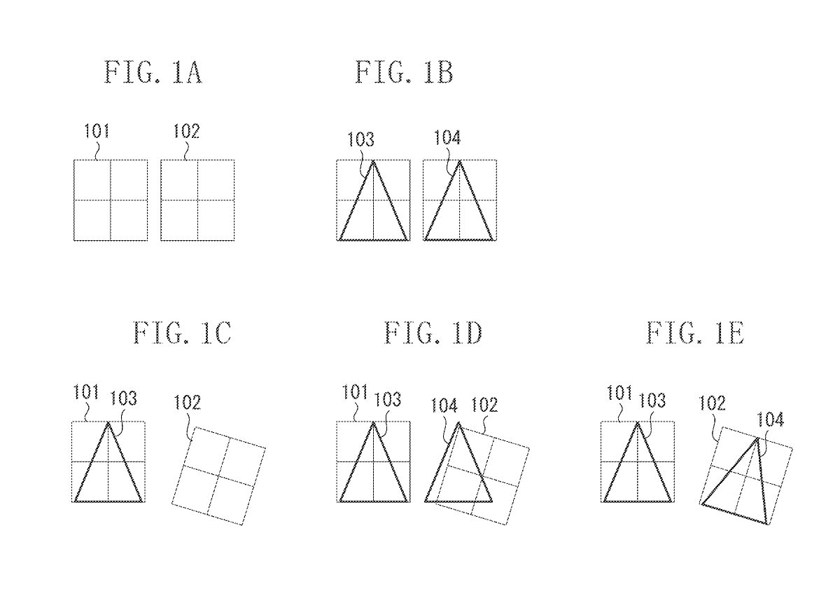

Before the descriptions of exemplary embodiments of a lithography apparatus according to the present invention, the reduction in the overlay accuracy of patterns resulting from heat is described in detail with reference to FIGS. 1A, 1B, 1C, 1D, and 1E.

In FIGS. 1A, 1B, 1C, 1D, and 1E, patterns of a first layer are represented as rectangles, and patterns of a second layer are represented as triangles. FIG. 1A illustrates a state where patterns 101 and 102 of the first layer have been properly formed. FIG. 1B illustrates a state where patterns 103 and 104 of the second layer have been properly formed and are not shifted in position relative to the patterns 101 and 102, respectively, of the first layer.

On the other hand, FIG. 1C illustrates a state where the patterns 101 and 102 of the first layer have been formed, and then, the pattern 103 of the second layer has been formed. Distortion has occurred in the pattern 102 due to the heat of the substrate when the pattern 103 has been formed. If the pattern 104 of the second layer is formed as planned without adjusting the positions of a beam and the substrate, an overlay error occurs in the patterns 102 and 104 as illustrated in FIG. 1D.

Therefore, to prevent the occurrence of an overlay error caused by thermal deformation as illustrated in FIG. 1D, it is necessary to correct the position where the pattern 104 is to be formed, taking into account the distortion of the pattern 102. For example, if the position of the pattern 102 has been checked in advance by measurement at the stage of FIG. 1C, the relative position between the beam and the substrate may be adjusted, whereby the pattern 104 can be formed as illustrated in FIG. 1E. This can prevent an overlay error.

As described above, if there is a concern about the influence of thermal deformation while a certain layer is being formed, it is necessary to, during the formation of patterns on one layer, measure with high accuracy the position of a pattern formed earlier and adjust the positions of the beam and the substrate as needed. An example of a lithography apparatus for achieving this using position measurement sensors for two types of marks is described below.

The exemplary embodiments of the lithography apparatus according to the present invention are described taking as an example a drawing apparatus that draws a pattern using an electron beam as a beam. The lithography apparatus according to the present invention, however, is not necessarily limited thereto, and can be applied also to a lithography apparatus that forms a pattern using other types of beam described above.

First, as a first exemplary embodiment, a case is described where drawing is performed using a single electron beam while a stage is moved back and forth to change the relative position between a substrate and an electron beam.

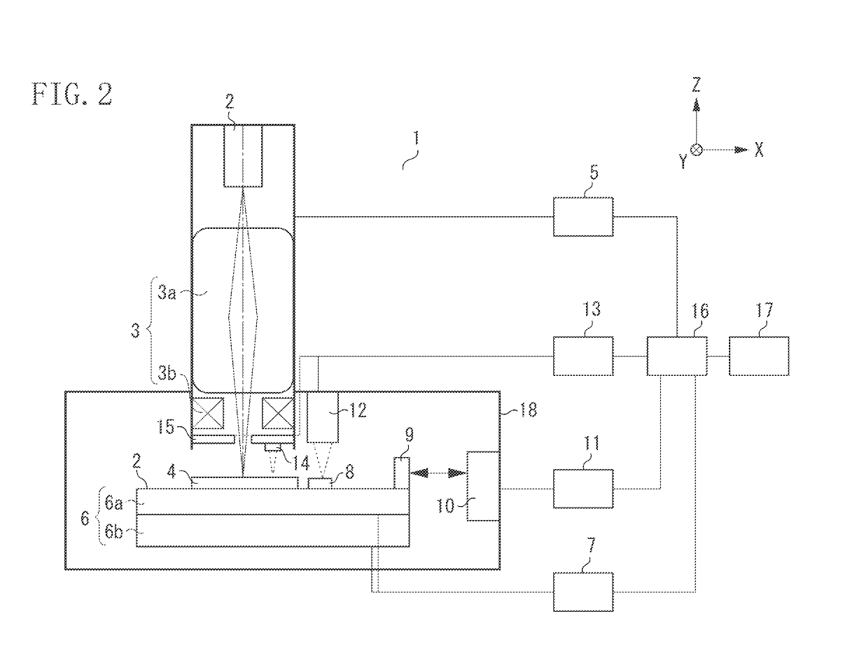

FIG. 2 is a diagram illustrating a configuration of a drawing apparatus 1 according to the first exemplary embodiment. The drawing apparatus 1 generally includes an electron source 2, an electron optical system 3, a substrate 4, a stage 6, an interferometer 10, an alignment sensor 12, a position correction sensor 14, a focus sensor 15, and a vacuum chamber 18.

The electron source 2 emits an electron beam and irradiates the surface of the substrate 4 with the emitted electron beam through the electron optical system 3. The electron optical system 3 includes an electron optical system 3a and a deflector 3b. The electron source 2 and the electron optical system 3 are controlled by a control unit 5.

The control unit 5 controls the electron optical system 3a to focus the electron beam and controls the deflector 3b to deflect the focused electron beam, thereby controlling the position of the electron beam irradiated to the surface of the substrate 4.

Further, if the degree of deflection by the deflector 3b is increased and the electron beam is shielded by metal, not only the on/off state of the electron source 2 but also the on/off state of the irradiation of the substrate 4 can be controlled at high speed. Thus, the control unit 5 can control the timing of irradiation by controlling the electron source 2 and the deflector 3b.

The stage 6 includes an X-stage 6a, a Y-stage 6b, and a Z-stage (not illustrated). The substrate 4 is held by the stage 6 and moves in an X-axis direction by the X-stage 6a, in a Y-axis direction by the Y-stage 6b, and in a Z-axis direction by the Z-stage. A position detection unit 11, which will be described below, detects the position of the stage 6. A control unit 13 controls measuring instruments. A control unit 7 controls the position of the stage 6. Based on position information about the substrate 4 sent from the position detection unit 11 and the control unit 13, the control unit 7 controls the position of the electron beam irradiated to the surface of the substrate 4.

On the stage 6, a reference plate 8, on which a reference mark is formed, is provided at a position different from the position of the substrate 4. An X-axis moving mirror 9 for determining the position of the substrate 4 in the X-axis direction is provided at one end of the X-stage 6a. Similarly, a Y-axis moving mirror (not illustrated) is provided on the Y-stage 6b. The configuration of the stage 6 is not limited to the configuration according to the present exemplary embodiment so long as the stage 6 is movable in the X, Y, and Z-axis directions while holding the substrate 4.

The interferometer 10 divides a laser beam into measurement light and reference light, thereby causing the measurement light and the reference light to be incident on the X-axis moving mirror 9 and a reference mirror provided within the interferometer 10, respectively. Then, the interferometer 10 causes the reflected measurement light and reference light to overlap and interfere with each other. The position detection unit 11 detects the intensity of the interference light, thereby measuring the position of the X-axis moving mirror 9 using the reference mirror as a reference. Similarly, an interferometer (not illustrated) for detecting the position of the stage 6 in the Y-axis direction measures the position of the stage 6 in the Y-axis direction.

The alignment sensor 12 serving as a first measurement unit irradiates a plurality of alignment marks formed on the substrate 4 and the reference mark formed on the reference plate 8 with light, thereby measuring the positions thereof. To reduce measurement errors caused by a process on the substrate 4, the light source of the alignment sensor 12 desirably outputs broadband wavelengths including a plurality of peak wavelengths. Further, the light source desirably outputs light in a wavelength band where a resist on the substrate 4 is not exposed to the light. Thus, the light source desirably outputs light continuously including light in the wavelength band of 400 nm or more, more desirably, in the wavelength band of 450 nm to 800 nm.

Then, the alignment sensor 12 forms an image of the reflected light from the alignment marks and the reference mark on a light-receiving sensor of the alignment sensor 12, thereby detecting the images of the various marks. Then, the control unit 13 obtains the positions of the alignment marks and the reference mark. Then, a main control unit 16, which will be described below, performs statistical processing based on position information about the stage 6 measured by the position detection unit 11 and the measured values of the plurality of alignment marks obtained by the control unit 13, thereby adjusting the position of the substrate 4.

The position correction sensor 14 serving as a second measurement unit uses light to measure the positions of a plurality of position correction marks formed on the substrate 4. Further, the position correction sensor 14 measures the positions of the position correction marks more frequently than the measurements by the alignment sensor 12.

The placement position of the position correction sensor 14 (a second measurement position) is a position closer to the electron optical system 3 than the placement position of the alignment sensor 12 (a first measurement position) is. To that end, the scale of the configuration of a lens group can be smaller in the position correction sensor 14 than that in the alignment sensor 12 as a result of providing fewer lenses for projecting light in the position correction sensor 14 than those in the alignment sensor 12. Further, a detection area for a mark can be consequently smaller than that of the alignment sensor 12, or the magnification of an image to be formed on a detection sensor can be consequently lower than that of the alignment sensor 12.

Alternatively, unlike the alignment sensor 12, the position correction sensor 14 does not necessarily have the function of switching wavelength bands of the light source, and options for the light source may be limited to only several wavelengths.

If the position correction sensor 14 has the above configuration, a measurement error is likely to occur due to the difference between lenses or the difference between light sources when the positions of the marks are detected. Meanwhile, the position correction sensor 14 can be designed to have a very compact configuration. Thus, the position correction sensor 14 can be placed even in a space where it is difficult to place the alignment sensor 12, such as a space under a column including the electron optical system 3.

Further, a detection unit of the position correction sensor 14 desirably includes a line sensor or a time delay integration (TDI) sensor, thereby detecting the reflected light from the marks to measure the positions of the marks. The use of such a sensor enables the measurements of the positions of the marks on the substrate 4 using the position correction sensor 14 even while drawing is being performed using the electron beam, for example. Alternatively, a measurement method of the position correction sensor 14 may be a method of detecting the intensity of the diffracted light from the marks to obtain the positions of the marks from the change in the intensity of the detected signal.

Thus, if the position correction sensor 14 is placed at a position close to the electron optical system 3, the amount of movement and the movement time of the substrate 4 required to measure the positions of the position correction marks can be reduced as compared to the case where the alignment sensor 12 measures the positions of the marks multiple times. Depending on the positions of the position correction marks, the positions of the position correction marks can be measured without reducing the number of times the drawing using the electron beam is suspended, or without moving the substrate 4. Further, providing a single electron optical system 3 with a plurality of position correction sensors 14 can enhance these effects.

The light source of the position correction sensor 14, however, desirably emits light having a wavelength of 450 nm or more so that a resist on the substrate 4 does not be chemically changed even if the resist is exposed to the light. The marks to be measured by the position correction sensor 14 may be different from the alignment marks, or may be used also as the alignment marks.

The focus sensor 15 receives an instruction from the control unit 13 and measures the surface position of the substrate 4. The focus sensor 15 is desirably an optical sensor or a capacitance sensor.

A control unit of the drawing apparatus 1 according to the present exemplary embodiment includes the control unit 5, the control unit 7, the control unit 13, the position detection unit 11, and the main control unit 16. A control unit according to the present invention, however, needs to include at least the control unit 5, the control unit 7, and the main control unit 16 among these components. Each control unit may be independently placed as illustrated in FIG. 2, or all the control units may be integrally placed on a single circuit board, so long as the function of each control unit is not impaired.

The control unit 13, which controls a measurement system, is connected to the alignment sensor 12, the position correction sensor 14, and the focus sensor 15. The control unit 13 receives an instruction from the main control unit 16, instructs these sensors to make measurements, and sends the obtained measurement results to the main control unit 16.

The main control unit 16 is connected to the control unit 5, the position detection unit 11, and the control unit 13. The main control unit 16 uses a central processing unit (CPU) included therein to control the other control units to execute programs stored in a memory 17. At this time, the main control unit 16 reads the programs stored in the memory 17, performs calculations requested from the other control units, or stores data sent from the control unit 13 or the position detection unit 11 in the memory 17.

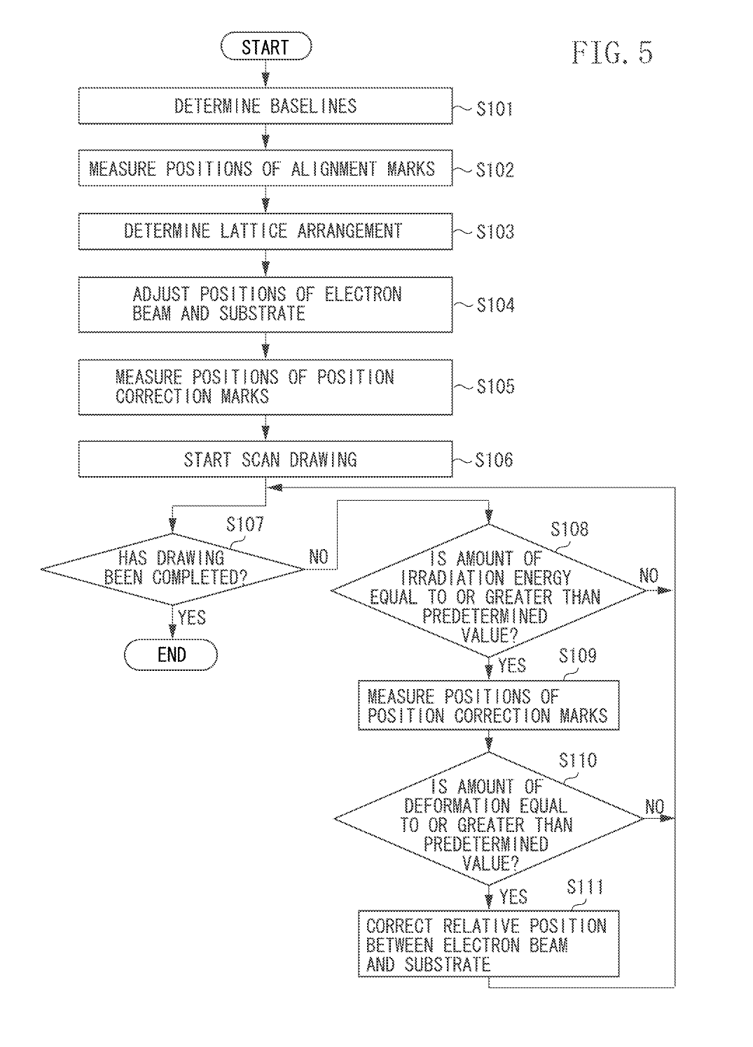

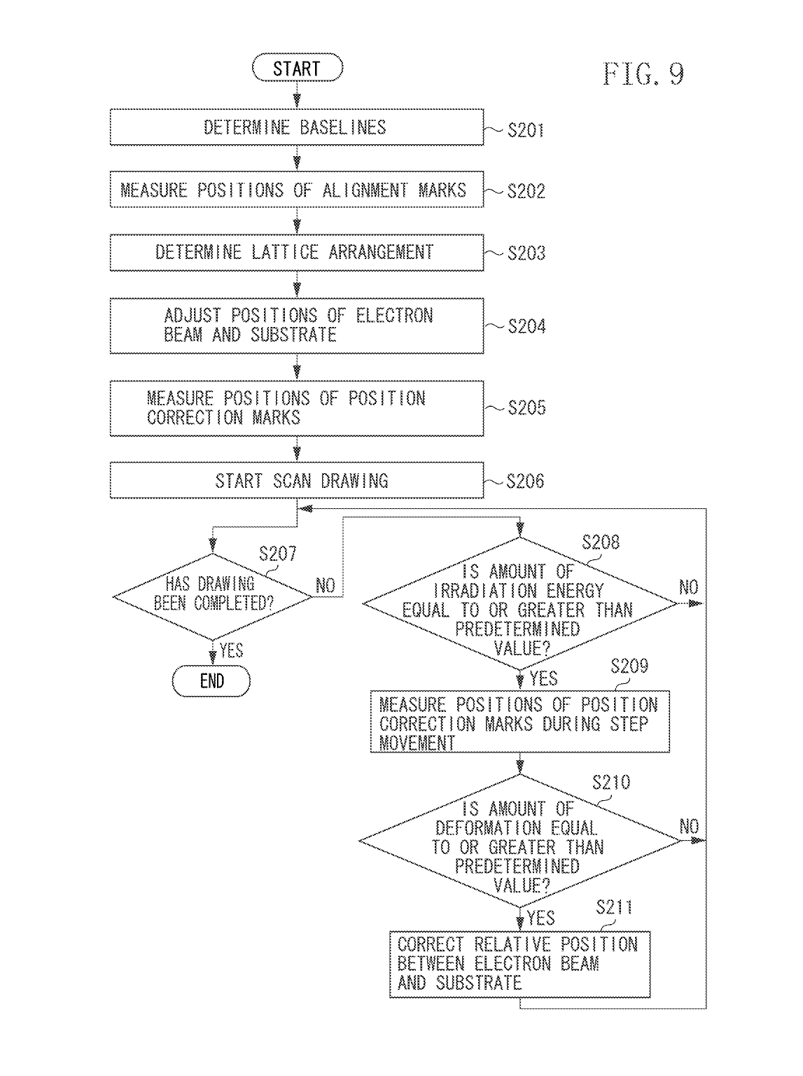

The memory 17 stores programs for performing processing illustrated in flow charts of FIGS. 5 and 9, the measured values of the positions of the marks measured using the alignment sensor 12 and the position correction sensor 14, and correction coefficients for position adjustments. The memory 17 also stores data indicating the relationship between the irradiation energy of the electron beam and the amount of deformation of the substrate 4.

In the vacuum chamber 18, the electron source 2, the electron optical system 3, the stage 6, the interferometer 10, the alignment sensor 12, the position correction sensor 14, and the focus sensor 15 are placed. A vacuum pump (not illustrated) exhausts air to create a vacuum inside the vacuum chamber 18.

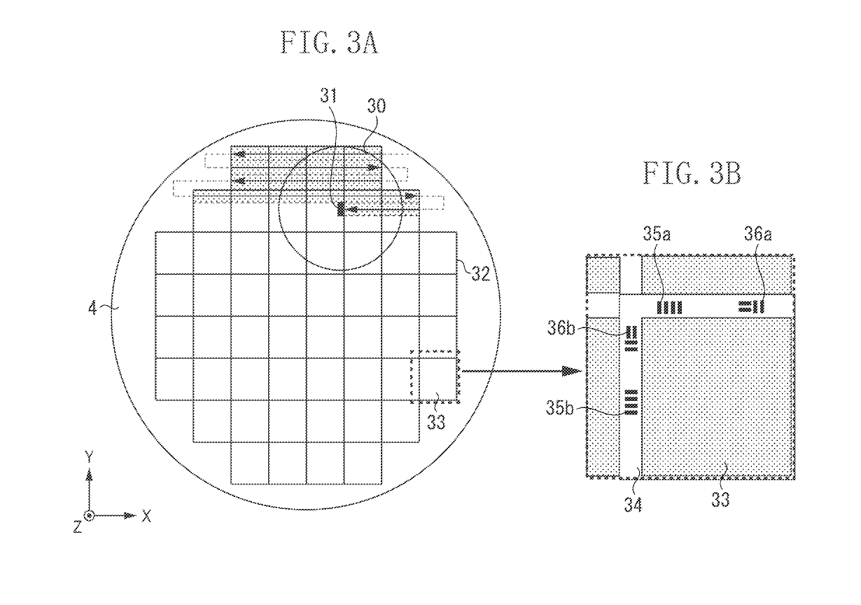

Before the description of the operation of the drawing apparatus 1 according to the present exemplary embodiment, a drawing method using the drawing apparatus 1 is described first with reference to FIG. 3A. At the center of a column 30 of the drawing apparatus 1, a drawing slit 31 for the electron beam is open. The electron beam is irradiated through the drawing slit 31 to draw patterns in a plurality of pattern drawing areas 32 on the substrate 4.

The deflector 3b deflects the electron beam in a direction parallel to the Y-axis, and the control unit 7 moves the stage 6 in the X-axis direction or the Y-axis direction, whereby the drawing is performed. At this time, scan drawing in which the drawing is performed while the stage 6 is moved in the X-axis direction and a step movement in which the stage 6 is moved in the Y-axis direction are collectively referred to as a “step-and-scan operation”. In FIGS. 3A and 3B, the scan drawing is represented by a solid line, and the step movement is represented by a dotted line.

Next, the alignment marks for the alignment sensor 12 and the position correction marks for the position correction sensor 14 are described.

FIG. 3B is an enlarged view illustrating the vicinity of the boundary of a shot area 33 (an area that is surrounded by a scribe line for forming the alignment marks and corresponds to one or more chip areas to be formed), which is one of the pattern drawing areas 32 illustrated in FIG. 3A. Around the shot area 33, a scribe line 34 is provided on which alignment marks 35a and 35b and position correction marks 36a and 36b are formed.

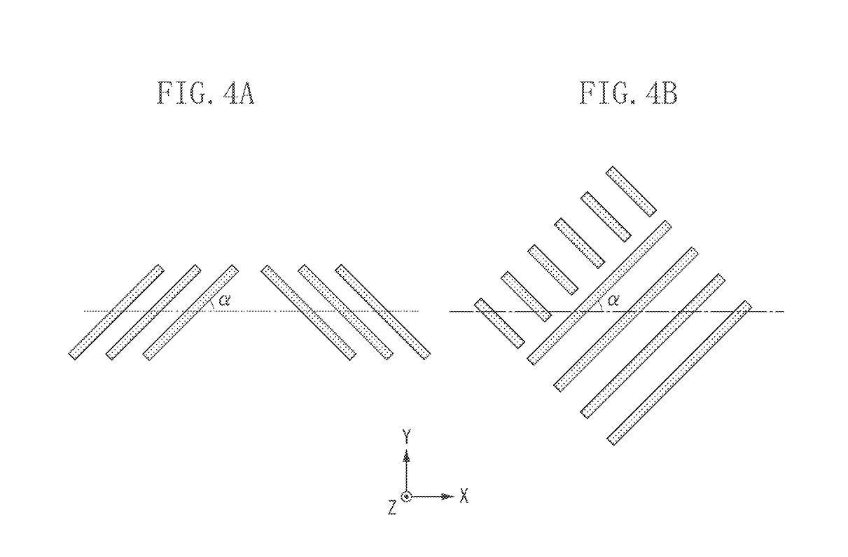

The position correction marks 36a and 36b are marks perpendicular to, or parallel to, the drawing direction of the electron beam (the X-axis direction). Position correction marks according to the present invention, however, are not limited thereto. A desirable exemplary embodiment is as illustrated in FIG. 3B because the signal intensity is large. Alternatively, as in marks illustrated in FIGS. 4A and 4B, the position correction marks may be arranged so that the longitudinal direction of the pattern is inclined by a degrees relative to the drawing direction of the electron beam (the X-axis direction).

Further, the patterns of the alignment marks and the position correction marks to be measured in the present exemplary embodiment may be the same as or different from each other. If each sensor has an optimal mark pattern, different marks may be desirably used for respective sensors in a distinguished manner. If the space in the scribe line 34 is taken into account, the same marks may desirably be used in a shared manner. For example, if a large number of layers are to be formed and it is necessary to secure space also for the formation of marks to be used for purposes other than position adjustments such as an examination, the alignment marks may be used also as the position correction marks.

The placement locations of the alignment marks and the position correction marks on the scribe line 34 may be set for a common shot area 33 or shot areas 33 different from each other.

Next, with reference to a flow chart illustrated in FIG. 5, a description is given of the content of the processing performed by the drawing apparatus 1 for measuring strain or deformation caused by heat to make correction. The flow chart of FIG. 5 illustrates a series of processes of a drawing method when the scan drawing is performed by scanning the substrate 4 with the electron beam in the +X-direction and the −X-direction as in FIG. 3A.

In step S101, the distance between the alignment sensor 12 and an optical axis of the electron optical system 3, i.e., the baseline, is determined using the reference mark formed on the reference plate 8.

First, the control unit 7 moves the stage 6 so that the reference mark is located on the optical axis of the alignment sensor 12, based on a design coordinate system. The design coordinate system is a coordinate system recognized by the main control unit 16, but may be shifted from a stage coordinate system actually recognized by the position detection unit 11.

Then, the control unit 13 controls the alignment sensor 12 to measure the position of the reference mark. Thus, the control unit 13 measures the positional shift of the reference mark relative to the optical axis. Based on the shift, the stage coordinate system is reset so that the origin of the stage coordinate system coincides with the optical axis.

Next, the control unit 7 moves the stage 6 so that the reference mark is located on the optical axis of the electron optical system 3 in the design coordinate system. A secondary electron detector (not illustrated) detects a secondary electron produced when the reference mark is scanned with the electron beam, to measure the position of the reference mark. The reference baseline between the optical axis of the electron optical system 3 and the optical axis of the alignment sensor 12 is thus determined. Similarly, the distance between the optical axis of the electron optical system 3 and the position correction sensor 14 is obtained to determine the reference baseline between the optical axis of the electron optical system 3 and the position correction sensor 14.

In step S102, the control unit 7 moves the stage 6 so that the alignment marks are located on the optical axis of the alignment sensor 12. The control unit 13 obtains the shifts between the positions of the alignment marks measured by the control unit 13 and the design positions of the alignment marks.

In step S103, the main control unit 16 determines a lattice arrangement on the substrate 4 by a global alignment method. Specifically, based on the measurement results in step S102, the main control unit 16 calculates shift, magnification, rotation, and trapezoidal components of each shot area 33 to correct each item.

Then, in step S104, the main control unit 16 obtains a correction coefficient from the lattice arrangement determined in step S103 and the reference baselines, and adjusts the positions of the electron beam and the substrate 4 based on the correction coefficient. At this time, the main control unit 16 stores the obtained correction coefficient in the memory 17.

In step S105, before the start of the drawing using the electron beam (irradiation of the electron beam), the single position correction sensor 14 measures the positions of the position correction marks. The position correction marks to be measured at this time are all the position correction marks to be measured again in step S109. Further, the position measurement values of the position correction marks are stored in the memory 17. Due to the structure of the position correction sensor 14, a measurement error caused by the lens configuration or the light source is more likely to occur than the case where the alignment sensor 12 makes the measurements. The influence of such a measurement error on subsequent processes, however, is small enough to be neglected. The reason for this will be described in detail when the subsequent processes are described.

Further, the number of the position correction marks to be measured may not be the same as the number of alignment marks. For example, the position correction sensor 14 may measure more position correction marks than alignment marks measured by the alignment sensor 12. This enables highly accurate correction of thermal deformation in the substrate 4 that occurs in the subsequent scan drawing process due to the heat of the drawing. Alternatively, the position correction sensor 14 may measure fewer position correction marks than alignment marks measured by the alignment sensor 12. This enables the suppression of the increases in the measurement time and the load of data processing for the position correction on the main control unit 16.

In step S106, the control unit 5, the control unit 7, and the position detection unit 11 receive an instruction from the main control unit 16 and start drawing a pattern by the step-and-scan operation. Before the drawing, the control unit 5 or the control unit 7 controls at least either of the deflector 3b and the stage 6 to operate so that the drawing slit 31 is located at one end of the pattern drawing areas 32.

In step S107, the main control unit 16 determines whether the drawing has been completed. If the main control unit 16 determines that the drawing has been completed in all the pattern drawing areas 32 on the substrate 4 (YES in step S107), the main control unit 16 ends the drawing operation and also ends the processing illustrated in the flow chart of FIG. 5. If, on the other hand, the main control unit 16 determines that the drawing has not been completed (NO in step S107), the processing proceeds to step S108.

In step S108, the main control unit 16 determines whether the amount of energy of irradiation of the substrate 4 since the drawing has started is equal to or greater than a predetermined value. If the main control unit 16 determines that the amount of energy is equal to or greater than the predetermined value (YES in step S108), the processing proceeds to step S109, and the position correction marks are measured. If the main control unit 16 determines that the amount of energy is less than the predetermined value (NO in step S108), the processing returns to step S107 to continue the drawing.

The reason why the amount of irradiation energy is used as a basis for determining whether to proceed to step S109 is that the heat accumulated in the substrate 4 results from the irradiation energy of the electron beam.

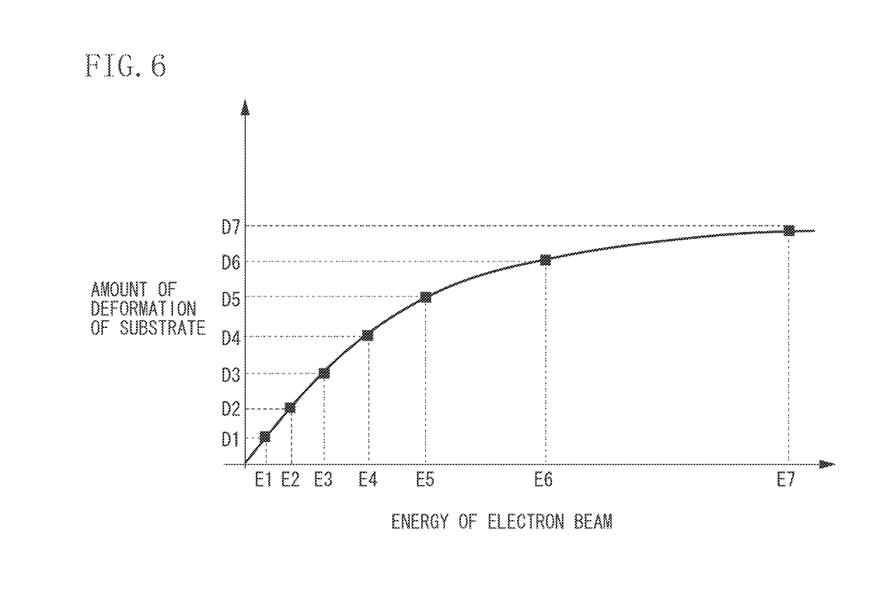

FIG. 6 illustrates the relationship between the amount of energy of the electron beam and the amount of deformation of the substrate 4, which is data saved in advance in the memory 17. Further, plots in FIG. 6 illustrate amounts of energy E1 to E7 of the electron beam, which are predetermined values for determining whether the position correction marks are to be measured. These values may be set in advance in the memory 17 or may be set by a user. Further, amounts of deformation D1 to D7 of the substrate 4 corresponding to the respective predetermined values do not need to be set for each certain amount.

Further, the determination of whether the amount of irradiation energy of the electron beam has reached the predetermined value may be made by calculations or actual measurements. For example, if the main control unit 16 takes into account the irradiation energy per unit time and the drawing pattern, the total amount of energy can be obtained by calculations. Alternatively, measuring instruments (not illustrated) for measuring the amount of irradiation energy may be placed below the deflector 3b, whereby a part of the electron beam can actually be measured.

Alternatively, based on values such as the positions of the position correction marks to be measured, the drawing pattern, and the actually measured amount of irradiation energy, a predetermined value as a criterion for the determination of whether to proceed to the next step can be changed each time the determination in step S108 is made.

In step S109, the control unit 13 controls the position correction sensor 14 to measure the positions of the same position correction marks as those measured in step S105. The total number of the position correction marks to be measured at this time, however, may be smaller than the number of the position correction marks measured in step S105. For example, position correction marks may be measured at several points in the areas where the drawing has yet to be performed. The positions and the number of the position correction marks to be measured may vary each time, depending on the position of the shot area 33 in which the drawing is being performed at that time, or depending on the drawing pattern.

The positions of the position correction marks is desirably measured during the step-and-scan operation. The positions of the position correction marks placed in the areas where the drawing has yet to be performed may be measured in parallel with the irradiation of the electron beam during the scan drawing. This enables the suppression of the increase in the measurement time. Alternatively, if the positions of the position correction marks are measured in parallel with the step movement, the stage 6 may be controlled so that the position correction marks pass through a measurement area of the position correction sensor 14.

In step S110, the main control unit 16 determines whether differences ΔD between the positions of the position correction marks measured in step S105 and the positions of the position correction marks measured in step S109 are equal to or greater than a predetermined value set in advance.

As described above, a measurement error is more likely to occur in measured values obtained by the position correction sensor 14 than those obtained by the alignment sensor 12. The position correction marks to be compared in step S110, however, are the same as each other and have been measured by the same sensor. Thus, sensor-specific measurement errors in the position correction marks are considered to be a similar level. Consequently, the influence of the measurement errors included in the differences ΔD between the positions of the marks measured in steps S105 and the positions of the marks measured in S109 becomes small enough to be neglected. Thus, the obtained differences ΔD are considered to correspond only to the amount of thermal deformation of the substrate 4.

If the main control unit 16 determines that the differences ΔD, which correspond to the amount of deformation or the like of the substrate 4, are equal to or greater than the predetermined value (YES in step S110), the processing proceeds to step S111, and the relative position between the electron beam and the substrate 4 are corrected. If the main control unit 16 determines that the differences ΔD are less than the predetermined value (NO in step S110), the processing returns to step S107 to continue the drawing operation.

This predetermined value indicates the allowable amount of shift. The predetermined value is desirably set based on the demanded drawing accuracy of the drawing apparatus 1 or based on drawing data. Further, the predetermined value does not necessarily need to be the same value each time. For example, every time the correction of the relative position between the electron beam and the substrate 4 is repeated, the predetermined value may be set to decrease according to the number of repetitions.

In step S109, a plurality of position correction marks are measured, and therefore, the differences ΔD may be equal to or greater than the predetermined value at some points and may be less than the predetermined value at other points, depending on the positions of the marks. In such a case, it may be determined to be YES if the differences ΔD are equal to or greater than the predetermined value at any one point. Alternatively, it may be determined to be YES if the differences ΔD are equal to or greater than the predetermined value at half or more of the measurement points.

In step S111, based on the plurality of differences ΔD, the main control unit 16 obtains the amount of correction in each area where the drawing has yet to be performed. Then, the main control unit 16 controls the control unit 7 to move the stage 6. This controls the relative position between the electron beam and the substrate 4 to adjust the positions of the electron beam and the substrate 4, thereby suppressing the reduction in the overlay accuracy.

Specifically, based on the difference ΔD at each measurement point, the main control unit 16 calculates the amount of correction required in the drawing area where the drawing has yet to be performed. Then, the main control unit 16 ensures that the drawing is to be performed taking into account the amount of correction obtained from the difference ΔD in addition to the correction data obtained when the positions of the electron beam and the substrate 4 have been adjusted in response to the measurement results of the alignment sensor 12 (step S104). The position of the irradiation of the electron beam may be controlled not only by the control unit 7 but also by the control unit 5 controlling the deflector 3b. Alternatively, the relative position between the substrate 4 and the electron beam may be controlled by the combination of the control units 7 and 5.

After the relative position between the electron beam and the substrate 4 has been corrected in step S111, the processing returns to step S107 to continue the drawing operation.

Then, the processes of steps S107 to S111 are performed until the main control unit 16 determines in step S107 that the drawing has been completed. The position correction marks to be measured in step S109 may vary every time the processes of steps S107 to S111 are repeated.

Further, in the above example, the timing of determining whether to measure the position correction marks for the second time and thereafter is determined based on the amount of energy of the electron beam irradiated to the substrate 4. The timing of making the determination, however, is not limited thereto.

The amount of strain or the amount of deformation of the substrate 4 varies depending on the amount of energy of the electron beam incident on the substrate 4, the time of irradiation, or the area of the irradiation. Thus, regarding the timing of determining whether to measure the position correction marks, the determination may be made, for example, at predetermined time intervals, or every time the drawing is performed through the drawing slit 31 for a predetermined number of slits, or every time the drawing is performed in a predetermined number of shot areas, or every time the drawing is completed in shot areas corresponding to one line.

The position correction marks measured in steps S105 and S109 do not necessarily need to be the same marks. It is possible to obtain similar effects so long as the mark measured in step S105 and the mark measured in step S109 are so close to each other that the amounts of deformation of the marks caused by heat are nearly equal. Although depending on the drawing pattern, the mark measured in step S105 and the mark measured in step S109 may be adjacent marks. Alternatively, the present invention also includes the case where the mark measured in step S105 and the mark measured in step S109 are so close to each other that a part of shot areas adjacent to the mark measured in step S105 and a part of shot areas adjacent to the mark measured in step S109 are shared (the marks are adjacent to a common shot area).

Adjacent shot areas refer to shot areas touching a scribe line on which a position correction mark is formed, in directions orthogonal to the scribe line with the position correction mark in the center.

If adjacent marks are measured before and after the irradiation of the electron beam, the positional relationship between the position of the mark to be measured first and the position of the mark to be measured next is obtained as offset data in advance.

The above configuration of the apparatus and the above content of the processing performed by the apparatus are the description of the present exemplary embodiment.

According to the present exemplary embodiment, alignment marks are measured using the alignment sensor 12 before the start of the drawing, that is, in the state where the substrate 4 is not deformed, and the shift in the relative position between the electron beam and the substrate 4 is corrected.

On the other hand, the position correction sensor 14 measures the positions of marks that share the same shot area or adjacent shot areas before and after the irradiation of the electron beam (at the different timings). One of the measurements of the position correction sensor 14 is made in the state where the substrate 4 is not deformed by the influence of heat. Then, the substrate 4 is irradiated with the electron beam, and based on the difference between the measured values obtained after thermal deformation has occurred in the substrate 4, each control unit corrects the shift in the relative position between the electron beam and the substrate 4 again.

As described above, the amount of deformation of the substrate 4 obtained by the measurements of the position correction sensor 14 is added to the correction result of the alignment sensor 12, which corrects position adjustments with high accuracy. This enables position adjustments taking into account the deformation during the drawing.

Further, the positions of the same mark are compared before and after strain or deformation occurs due to heat. This enables position adjustments with higher accuracy than the case of making position adjustments using an electron beam.

It is difficult to realize the present invention using only one type of sensor. If only the alignment sensor 12 is provided, the amount of movement of the stage 6 increases when a measurement is made at a given timing. If, on the other hand, only the position correction sensor 14 is used, a measurement error is likely to occur due to the lens configuration or the light source of the position correction sensor 14 itself. Thus, it is difficult to make position adjustments with high accuracy.

Further, the example has been described where the position correction sensor 14 measures the positions of the position correction marks during the scan drawing or the step movement. Alternatively, the processing may include the operation of suspending the drawing and moving the substrate 4 to measure position correction marks located at positions distant from the optical axis. Even if the suspension of the drawing is included, it is still possible to make the movement time of the substrate 4 shorter than the case where the alignment sensor 12 makes the measurements instead of the position correction sensor 14. Thus, it is possible to obtain the effect of improving the throughput.

A second exemplary embodiment is described. The present exemplary embodiment is different from the first exemplary embodiment in that a drawing apparatus 1 according to the present exemplary embodiment includes a plurality of position correction sensors 14a to 14c for a single electron optical system 3. Further, the processing performed by each control unit is similar to that in the flow chart illustrated in FIG. 5, except for the method for measuring position correction marks. Thus, the similar processing content is not described here.

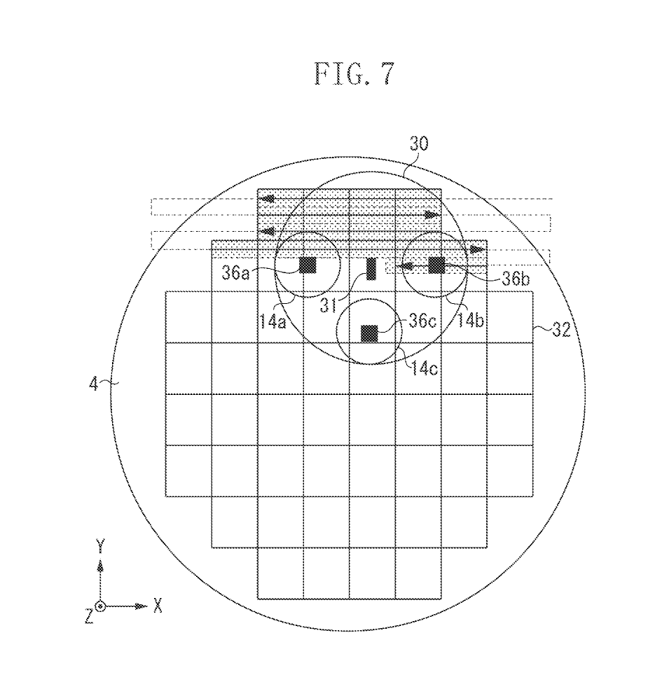

FIG. 7 is a diagram illustrating the state of the drawing performed by the drawing apparatus 1 according to the present exemplary embodiment. The present exemplary embodiment is characterized in that the drawing apparatus 1 includes three position correction sensors 14a to 14c for the single electron optical system 3. The position correction sensors 14a to 14c are respectively placed in the +X-axis direction, the −X-axis direction, and the −Y-axis direction relative to the drawing slit 31.

An increase in the number of position correction sensors 14 enables the measurements of three position correction marks 36a to 36c at a time even during the drawing, for example. If the drawing is suspended only for a short time, it is possible to move the positions of the electron beam and the substrate 4 relative to each other, thereby measuring position correction marks at three points in areas where the drawing has yet to be performed.

The present exemplary embodiment is characterized in that the plurality of position correction sensors 14a to 14c are thus provided. It is possible to reduce the number of times the drawing is suspended as compared to the first exemplary embodiment, and to secure more measurement points for the positions of marks than the first exemplary embodiment, in which only one position correction sensor 14 is provided. This can improve the throughput while maintaining the correction accuracy according to the first and second exemplary embodiments. At this time, the total moving distance of the stage 6 required for the plurality of position correction sensors 14a to 14c to measure a plurality of position correction marks is desirably as short as possible. Thus, the main control unit 16 desirably selects in advance the position correction sensor 14 to be used for measurements and position correction marks to be measured.

Further, the number of a plurality of position correction sensors 14 is not limited to three. Further, the placement of the position correction sensors 14 is not limited to that illustrated in FIG. 7. Alternatively, the position correction sensors 14 may be asymmetrically placed, or may be unevenly distributed in the moving direction of the drawing.

In the adjustments of the positions of the electron beam and the substrate 4, the configuration in which a plurality of position correction sensors 14 are placed also has an advantage over the configuration in which a plurality of alignment sensors 12 are placed, in that the cost of the apparatus is lower.

If, however, the positions of the marks are measured using a plurality of position correction sensors 14 as in the present exemplary embodiment, it is desirable to obtain in advance measurement errors between the position correction sensors 14 caused by the individual differences between the sensors. This is because the present exemplary embodiment is characterized in that the difference between the results of the measurements of the position of the same position correction mark is obtained to cancel out the measurement errors that occur when the position correction sensors 14 make the measurements.

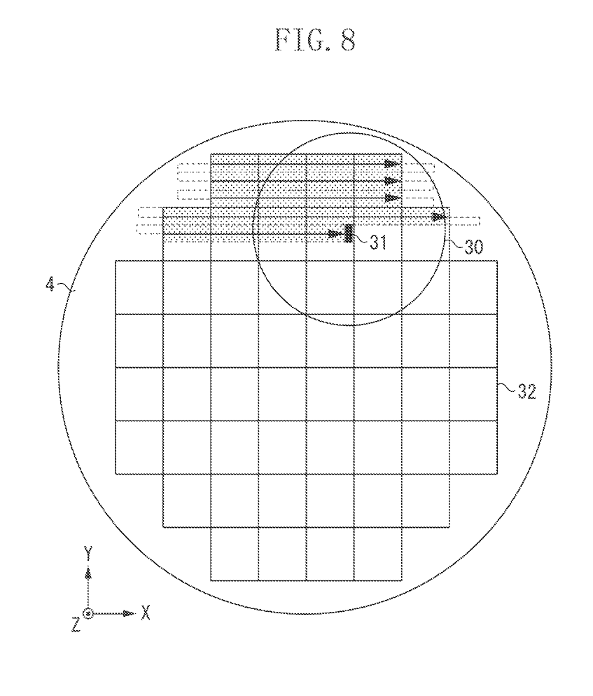

Next, a third exemplary embodiment is described. In the third exemplary embodiment, as illustrated in FIG. 8, the drawing apparatus 1 performs unidirectional scan drawing (a solid line) only in the +X-direction. That is, the third exemplary embodiment is different from the first exemplary embodiment in that after the position of the drawing slit 31 has been adjusted to a drawing start position and the scan drawing has been performed in the +X-direction, the step movement is made so that the drawing slit 31 is located in the −Y-axis direction and the −X-direction relative to the substrate 4. Further, the third exemplary embodiment is also different from the first exemplary embodiment in that a program for performing processing illustrated in a flow chart of FIG. 9 is stored in the memory 17. The remaining configuration of the apparatus is similar to that according to the first exemplary embodiment.

The processes of steps S201 to S208 in the flow chart of FIG. 9 are similar to the processes of steps S101 to S108 in FIG. 5, and steps S210 to S211 in FIG. 9 are similar to steps S110 to S111 in FIG. 5. Thus, these steps are not described here.

In the process of step S209 in FIG. 9, the timing when the position correction sensor 14 measures the position correction marks is during the step movement. This provides the following two characteristics: (A) the degree of freedom of the moving route when the position correction sensor 14 measures the position correction marks during the step movement is higher than that of the drawing method according to the first exemplary embodiment; and (B) the processing is less likely to be influenced by heat than the drawing method according to the first exemplary embodiment. These characteristics are described below.

(A) In the first exemplary embodiment, the step movement is limited to the −Y-axis direction, and the moving distance of the step movement is short. This limits the number and the positions of position correction marks that can be measured during the step movement. In contrast, in the present exemplary embodiment, the step movement is made not only in the −Y-axis direction but also in the −X-direction. Thus, the moving distance of the step movement is long. This enables the measurements of a plurality of position correction marks during the movement to the next scan drawing start position by the step movement.

Further, the degree of freedom in the selection of a route for the movement to the next scan drawing start position is high. This facilitates the appropriate selection of a route during the step movement, according to the number of the marks to be measured and the positions of the marks to be measured. Thus, when the shift, magnification, and rotation are calculated to make correction, it is possible to make the correction with high accuracy.

(B) In the case of the back-and-forth scan drawing as in the first exemplary embodiment, the position where the drawing of shot areas 33 corresponding to one line has been completed is close to the position where the next drawing is to start. Thus, the processing is likely to be influenced by the heat at the position where the drawing of the one line has been completed. If the heat is not sufficiently diffused, thermal deformation may progress at the next drawing start position.

In contrast, in the present exemplary embodiment, the position where the drawing of shot areas 33 corresponding to one line has been completed is sufficiently distant from the position where the next drawing is to start. Further, the positions of the position correction marks are measured mainly during the step movement. Thus, in the third exemplary embodiment, the position correction marks are measured in the state where thermal diffusion and cooling have progressed in the substrate 4 with the lapse of time as compared to the first exemplary embodiment. Thus, strain or deformation that occurs after the measurements of the position correction marks is considered to be smaller than that in the first exemplary embodiment. This enables the correction of the shift in the relative position between the electron beam and the substrate 4 with high accuracy.

For the above reasons, according to the present exemplary embodiment, it is possible to correct the shift in the relative position between the electron beam and the substrate 4 with higher accuracy than the first and second exemplary embodiments. Thus, it is desirable that the first exemplary embodiment and the present exemplary embodiment are appropriately used depending on the throughput and the overlay accuracy demanded by the user.

The description has been given only of the case where the positions of the marks are measured using the position correction sensor 14 during the operation of the step movement. The scope of application of the present invention, however, is not limited thereto. For example, the positions of the marks may be measured during each of the operations of the scan drawing and the step movement, thereby obtaining the influence of the heat of the scan drawing after the measurements, from the comparison between the position measurement values during both operations. Thus, even when the positions of the marks are measured during the operation of the scan drawing as in the first exemplary embodiment, it is possible to correct the shift in the relative position between the substrate 4 and the electron beam taking into account the influence of the heat of the scan drawing after the measurements.

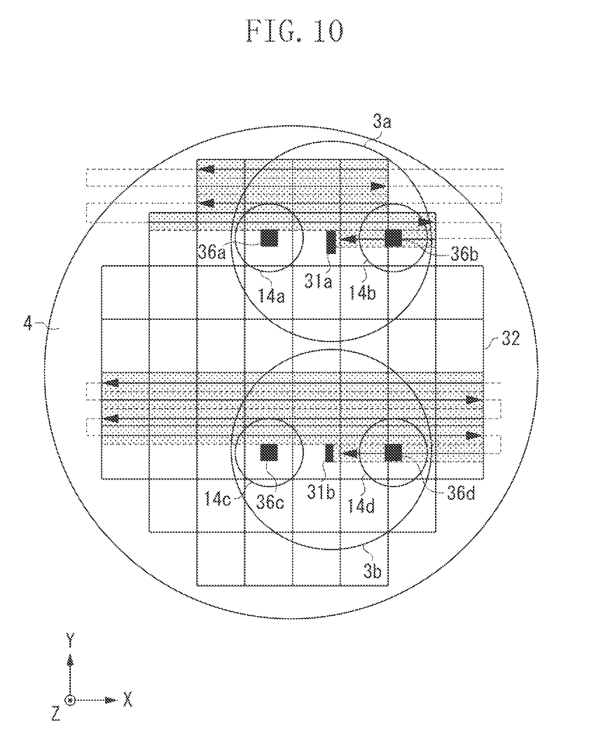

Next, a fourth exemplary embodiment is described. FIG. 10 is a diagram illustrating the state of the drawing performed by a drawing apparatus 1 that includes a plurality of electron optical systems. The fourth exemplary embodiment is different from the first, second, and third exemplary embodiments in that the drawing apparatus 1 according to the fourth exemplary embodiment includes a plurality of electron optical systems 3a and 3b placed in parallel with the Y-axis direction. Further, the processing performed by each control unit is similar to that in the flow charts illustrated in FIGS. 5 and 9, except for the method for measuring position correction marks. Thus, the similar processing content is not described here.

Electron beams are emitted through drawing slits 21a and 21b provided at lower ends of the electron optical systems 3a and 3b, thereby drawing desired patterns in pattern areas 32 on the substrate 4. Thus, it is possible to finish drawing desired patterns in a shorter time than the other exemplary embodiments.

Further, as illustrated in FIG. 10, the combination of the present exemplary embodiment and the second exemplary embodiment can improve the throughput. FIG. 10 is an example of the combination of the present exemplary embodiment and the second exemplary embodiment. Two position correction sensors 14a and 14b are placed for the electron optical system 3a, and two position correction sensors 14c and 14d are placed for the electron optical system 3b. This combination has the advantage that the positions of a plurality of position correction marks 36a to 36d can be measured at a time. Further, the marks 36a to 36d are placed at locations somewhat distant from one another on the substrate 4. This enables the detection of more overall thermal deformation. This enables the adjustments of the positions of the electron beam and the substrate 4 with high accuracy and at high speed, taking into account strain or deformation caused by heat.

Finally, a supplementary description common to the first to fourth exemplary embodiments is given.

As the timing when the position correction sensor 14 makes a measurement for the first time, the time before the start of the drawing using the electron beam (before a start of irradiation of the beam) has been exemplified. The scope of application of the present invention, however, is not limited thereto. Even before the start of the drawing or after the start of the drawing (after the start of the irradiation), the position correction sensor 14 may make a measurement at least once by a predetermined timing when strain or deformation of the substrate 4 caused by the heat of the drawing is considered to be extremely small.

If the position correction sensor 14 makes a measurement for the first time before the start of the drawing, either the first measurement of the alignment sensor 12 or the first measurement of the position correction sensor 14 may be made first.

Further, the configuration of the apparatus may be such that a dedicated movement stage is placed to make the position correction sensor 14 movable so that the measurements of the positions of the position correction marks and the scan drawing can be performed in a parallel manner. This reduces the time required for the position correction sensor 14 to make the measurements by suspending the scan drawing, and therefore improves the throughput.

When the position correction marks are measured, the number of times an X-position correction mark is measured may be different from the number of times a Y-position correction mark is measured. Alternatively, when the position correction marks are measured at a single time, more marks of one type may be measured than those of the other type. This is because if thermal deformation in the X-axis direction is greater than in the Y-axis direction, it is possible to correct the shift in the relative position between the electron beam and the substrate 4 with high accuracy. Examples of an exemplary embodiment in which strain or deformation is likely to occur in a constant direction include the case where the drawing is performed using drawing slits 31a and 31b arranged in a line in the Y-axis direction as in the fourth exemplary embodiment, and the case where a drawing pattern is biased in a constant direction.

### (Method for Manufacturing Device)

A method for manufacturing a device according to the present invention includes a process of scanning with an electron beam to compensate for the reduction in the overlay accuracy resulting from the heat generation during the drawing performed based on the above exemplary embodiments, and a process of developing a substrate on which patterns have been drawn. The method may further include other known processes (oxidation, film formation, deposition, doping, planarization, etching, resist separation, dicing, bonding, and packaging).

Further, the method according to the present invention has an advantage over a conventional method in terms of at least one of the performance, the quality, the productivity, and the production cost of the device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-096008 filed Apr. 30, 2013, which is hereby incorporated by reference herein in its entirety.

What is claimed is:

1. An apparatus comprising:
an optical system configured to irradiate a surface of a substrate with a beam;
a first measurement unit and a second measurement unit each configured to measure a position of a mark formed on the substrate, the second measurement unit being placed at a position closer to an optical axis of the optical system than the first measurement unit; and
a control unit configured to control a position of the beam irradiated to the surface of the substrate based on a position measurement value measured by the first measurement unit and position measurement values measured at different timings by the second measurement unit,
wherein the position measurement values measured at the different timings are values obtained from the same mark or values obtained from two marks adjacent to a common shot area.

2. The apparatus according to claim 1, wherein the different timings are timings before and after irradiation of the beam.

3. The apparatus according to claim 1, wherein the first measurement unit and the second measurement unit measure the position of the mark using light.

4. The apparatus according to claim 1, wherein the control unit obtains an amount of correction indicating a positional shift of the mark based on the position measurement values measured at the different timings, and controls the position of the beam irradiated to the surface of the substrate based on a corrected result of, corrected using the amount of correction indicating a positional shift of the mark, the position measurement value measured by the first measurement unit.

5. The apparatus according to claim 4, wherein the amount of correction indicating the positional shift of the mark is a difference between the position measurement values measured at the different timings.

6. The apparatus according to claim 1, wherein the second measurement unit makes measurement at least once before a start of irradiation of the beam, or by a predetermined timing after the start of the irradiation.

7. The apparatus according to claim 1, wherein the apparatus includes a plurality of second measurement units.

8. The apparatus according to claim 7, wherein a second measurement unit to be used for measurement is selected based on a distance between the optical system and the mark.

9. The apparatus according to claim 3, wherein the first measurement unit emits light including more peak wavelengths than the second measurement unit.

10. The apparatus according to claim 1, wherein if a direction in which the substrate moves relative to the optical system during irradiation of the beam is constant, the second measurement unit makes measurement during a step movement of the substrate.

11. An apparatus comprising:
an optical system configured to irradiate a surface of a substrate with a beam;
a first measurement unit and a second measurement unit each configured to measure a position of a mark formed on the substrate, the second measurement unit being placed at a position closer to an optical axis of the optical system than the first measurement unit; and
a control unit configured to control, based on a position measurement value measured by the first measurement unit and position measurement values measured at different timings by the second measurement unit, a position of the beam irradiated to the surface of the substrate,
wherein the position measurement values measured at the different timings are values obtained from the same mark or values obtained from marks adjacent to each other.

12. A method including irradiating a surface of a substrate with a beam through an optical system, the method comprising:
measuring a position of a mark formed on the substrate at a first measurement position and a second measurement position closer to an optical axis of the optical system than the first measurement position; and
controlling a position of the beam irradiated to the surface of the substrate based on a position measurement value measured at the first measurement position and position measurement values measured at different timings at the second measurement position,
wherein the position measurement values measured at the different timings are values obtained from the same mark or values obtained from two marks adjacent to a common shot area.

13. A method for manufacturing a device, the method comprising:
irradiating a substrate with a beam using an apparatus; and
developing the irradiated substrate,
wherein the apparatus includes:
an optical system configured to irradiate a surface of a substrate with a beam;
a first measurement unit and a second measurement unit configured to measure a position of a mark formed on the substrate, the second measurement unit being placed at a position closer to an optical axis of the optical system than the first measurement unit; and
a control unit configured to control, based on a position measurement value measured by the first measurement unit and position measurement values measured at different timings by the second measurement unit, a position of the beam irradiated to the surface of the substrate,
wherein the position measurement values measured at the different timings are values obtained from the same mark or values obtained from two marks adjacent to a common shot area.

14. The method according to claim 12, wherein the different timings are timings before and after irradiation of the beam.

15. The method according to claim 12, wherein the position of the mark is measured using light.

16. The method according to claim 12, further comprising:
obtaining an amount of correction indicating a positional shift of the mark based on the position measurement values measured at the different timings; and
controlling the position of the beam irradiated to the surface of the substrate based on a corrected result of, corrected using the amount of correction indicating a positional shift of the mark, the first position measurement value.

17. The method according to claim 16, wherein the amount of correction indicating the positional shift of the mark is a difference between the position measurement values measured at the different timings.

18. The method according to claim 12, wherein the second measurement position is measured at least once before a start of irradiation of the beam, or by a predetermined timing after the start of the irradiation.
